(19) United States
(12) Patent Application Publication
(10) Pub. No.: US 2021/0021038 A1
(43) Pub. Date: Jan. 21, 2021

(54) COMMUNICATION MODULE, ELECTRONIC DEVICE, AND COMMUNICATION MODULE MANUFACTURING METHOD

(71) Applicant: Murata Manufacturing Co., Ltd., Nagaokakyo-shi (JP)

(72) Inventor: Takanori TSUCHIYA, Nagaokakyo-shi (JP)

(21) Appl. No.: 17/061,646

(22) Filed: Oct. 2, 2020

Related U.S. Application Data
(63) Continuation of application No. PCT/JP2019/022996, filed on Jun. 10, 2019.

(30) Foreign Application Priority Data
Jun. 25, 2018 (JP) 2018-120311

(51) Int. Cl. H01Q 7/06; H01Q 9/04; H01Q 5/35; H01Q 9/16; H01Q 1/22; H01Q 21/06

(52) U.S. Cl. CPC H01Q 7/06; H01Q 9/0414; H01Q 21/065; H01Q 9/16; H01Q 1/2283; H01Q 5/35

(57) ABSTRACT

A communication module includes a multilayer substrate, a coil antenna, a component mounting electrode, a communication circuit unit, and a resin layer. The multilayer substrate includes a magnetic layer and a non-magnetic layer. The magnetic layer is on the side closer to a first principal surface of the multilayer substrate, and the non-magnetic layer is on the side closer to a second principal surface of the multilayer substrate. The coil antenna is in contact with the non-magnetic layer, and a ground electrode is provided inside the magnetic layer. A relay electrode is provided on or in the first principal surface of the multilayer substrate, an outer electrode is provided on or in an outer surface of the resin layer, and a wiring electrically connecting the relay electrode and the outer electrode is provided in the resin layer.

### CROSS REFERENCE TO RELATED APPLICATIONS

This application claims the benefit of priority to Japanese Patent Application No. 2018-120311 filed on Jun. 25, 2018 and is a Continuation Application of PCT Application No. PCT/JP2019/022996 filed on Jun. 10, 2019. The entire contents of each application are hereby incorporated herein by reference.

### BACKGROUND OF THE INVENTION

### 1. Field of the Invention

The present invention relates to a communication module, and more particularly, to a communication module including a multilayer substrate, a coil antenna, and a communication circuit. The present invention further relates to an electronic device, and more particularly, to an electronic device including a communication module and a circuit board. The present invention still further relates to a communication module manufacturing method suitable for manufacturing the communication module according to the present invention.

### 2. Description of the Related Art

A communication module including a coil antenna is widely used in radio communication equipment. For example, Japanese Unexamined Patent Application Publication No. 2014-79014 discloses this type of communication module. FIG. 10 illustrates a communication module 1000 disclosed in Japanese Unexamined Patent Application Publication No. 2014-79014.

The communication module 1000 includes a multilayer substrate 104 in which a first non-magnetic layer 101, a magnetic layer 102, and a second non-magnetic layer 103 are laminated.

A first coil pattern 105 is formed between layers defining the first non-magnetic layer 101, and a second coil pattern 106 is formed between layers defining the second non-magnetic layer 103. The first coil pattern 105 and the second coil pattern 106 are connected by a via conductor (via hole conductor) 107 that penetrates through the magnetic layer 102. A coil antenna (antenna coil) 108 is formed by the first coil pattern 105, the via conductor 107, and the second coil pattern 106.

An IC (IC chip) 109 and a passive component (capacitor chip) 110 are mounted to a lower principal surface of the multilayer substrate 104. A resin layer (sealing resin layer) 111 is formed to cover the IC 109 and the passive component 110.

The communication module 1000 is able to perform radio communication using the coil antenna 108. In FIG. 10, magnetic flux generated by the coil antenna 108 is denoted by dotted lines with arrows.

In the communication module 1000, as seen in FIG. 10, the coil antenna 108 generates a magnetic field in a direction perpendicular to principal surfaces of the multilayer substrate 104. Therefore, the magnetic field generated by the coil antenna 108 passes through the IC 109 and the passive component 110 that are mounted to the lower principal surface of the multilayer substrate 104.

Accordingly, in the communication module 1000, there is a possibility that formation of the magnetic field by the coil antenna 108 is impeded by the IC 109 and the passive component 110, and that a sufficiently long communication distance cannot be obtained. Because the magnetic field generated by the coil antenna 108 interlinks with a circuit formed by the IC 109 and the passive component 110, in the communication module 1000, there is also a possibility that radiation noise is generated and adversely affects the circuit.

In the communication module 1000, because the IC 109 and the passive component 110 are not shielded, there is another possibility that noise enters the IC 109 and the passive component 110 from the outside, thereby causing the IC 109 and the passive component 110 to malfunction. Furthermore, because the IC 109 and the passive component 110 are not shielded, in the communication module 1000, there is another possibility that noise is radiated to the outside from the IC 109 and the passive component 110.

### SUMMARY OF THE INVENTION

Preferred embodiments of the present invention provide the following solutions.

A communication module according to a preferred embodiment of the present invention includes a multilayer substrate including a first principal surface, a second principal surface, and at least one side surface that connects the first principal surface and the second principal surface; a coil antenna; a component mounting electrode provided on or in the first principal surface of the multilayer substrate; a communication circuit unit mounted to the first principal surface of the multilayer substrate with the component mounting electrode interposed therebetween; and a resin layer covering the communication circuit unit on the first principal surface side of the multilayer substrate, wherein the multilayer substrate includes a magnetic layer and a non-magnetic layer, the magnetic layer is positioned on the side closer to the first principal surface of the multilayer substrate, the non-magnetic layer is positioned on the side closer to the second principal surface of the multilayer substrate, the coil antenna is in contact with the non-magnetic layer, a ground electrode is provided inside the magnetic layer, a relay electrode is provided on or in the first principal surface of the multilayer substrate, an outer electrode is provided on or in an outer surface of the resin layer, and a wiring electrically connecting the relay electrode and the outer electrode is provided in the resin layer.

An electronic device according to a preferred embodiment of the present invention includes a communication module, and a circuit board to which the communication module is mounted, the communication module including a multilayer substrate including a first principal surface, a second principal surface, and at least one side surface that connects the first principal surface and the second principal surface; a coil antenna; a component mounting electrode provided on or in the first principal surface of the multilayer substrate; a communication circuit unit mounted to the first principal surface of the multilayer substrate with the component mounting electrode interposed therebetween; and a resin layer covering the communication circuit unit on the first principal surface side of the multilayer substrate, wherein the multilayer substrate includes a magnetic layer and a non-magnetic layer, the magnetic layer is positioned on the side closer to the first principal surface of the multilayer substrate, the non-magnetic layer is positioned on the side closer to the second principal surface of the multilayer substrate, the coil antenna is in contact with the non-magnetic layer, a ground electrode is provided inside the magnetic layer, a relay electrode is provided on or in the first principal surface of the multilayer substrate, and an outer electrode is provided on or in an outer surface of the resin layer, and a wiring electrically connecting the relay electrode and the outer electrode is provided in the resin layer, the communication module being mounted to the circuit board with the outer electrode interposed therebetween.

A communication module manufacturing method according to a preferred embodiment of the present invention includes a step of preparing a plurality of green sheets made of a magnetic substance and a plurality of green sheets made of a non-magnetic substance; a step of, to form via conductors, forming through-holes at desired positions in one or more among the plurality of green sheets made of the magnetic substance and one or more among the plurality of green sheets made of the non-magnetic substance, and filling a conductive paste into the through-holes; a step of coating a conductive paste in a pattern shape over a principal surface of each of one or more among the plurality of green sheets made of the magnetic substance and one or more among the plurality of green sheets made of the non-magnetic substance to form at least one selected from a coil pattern, a ground electrode, a component mounting electrode, a relay electrode, and a wiring; a step of laminating the plurality of green sheets made of the magnetic substance and the plurality of green sheets made of the non-magnetic substance, integrating the laminated green sheets into a one-piece structure, and firing the green sheets to fabricate a multilayer substrate that includes a first principal surface, a second principal surface, and at least one side surface that connects the first principal surface and the second principal surface, and that includes a magnetic layer formed on the side closer to the first principal surface, a non-magnetic layer formed on the side closer to the second principal surface, and a coil antenna formed by the coil pattern at a position in contact with the non-magnetic layer; a step of bonding an electronic component to the component mounting electrode formed on or in the first principal surface of the multilayer substrate, and bonding a metal pole to the relay electrode formed on or in the first principal surface of the multilayer substrate; a step of forming a resin layer on the first principal surface side of the multilayer substrate to cover the electronic component and the metal pole; and a step of scraping an outer surface of the resin layer to make an end surface of the metal pole exposed at the outer surface of the resin layer.

Since the communication modules according to preferred embodiments of the present invention are designed such that a magnetic field (magnetic flux) generated by the coil antenna is bent inside the magnetic layer to extend in a spread direction of the magnetic layer and is less likely to reach the communication circuit unit, formation of the magnetic field by the coil antenna is less likely to be impeded by the communication circuit unit. Furthermore, with the communication modules according to preferred embodiments of the present invention, since the ground electrode provided inside the magnetic layer defines and functions also as a shield electrode, noise is less likely to enter the communication circuit unit from the outside and noise is less likely to be radiated to the side including the coil antenna and to the outside from the communication circuit unit.

The electronic devices according to preferred embodiments of the present invention each include a communication module in which the formation of the magnetic field by the coil antenna is less likely to be impeded by the communication circuit unit, noise is less likely to enter the communication circuit unit from the outside, and noise is less likely to be radiated to the side including the coil antenna and to the outside from the communication circuit unit.

With the communication module manufacturing methods according to preferred embodiments of the present invention, the communication modules according to preferred embodiments of the present invention can be manufactured more easily.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a perspective view of a communication module 100 according to a first preferred embodiment of the present invention, and FIG. 1B is an exploded perspective view of the communication module 100.

FIG. 2 is a sectional view of the communication module 100.

FIG. 3 show a set of plan views of non-magnetic element layers 2a to 2d and magnetic element layers 3a to 3d that are laminated to define a multilayer substrate 1 of the communication module 100.

FIG. 4 is an explanatory view illustrating an example of usage of the communication module 100.

FIGS. 5A to 5C are sectional views illustrating steps performed in an example of a method for manufacturing the communication module 100 according to a preferred embodiment of the present invention.

FIGS. 6D and 6E are a continuation of FIG. 5C and are sectional views illustrating steps performed in the example of the method for manufacturing the communication module 100 according to a preferred embodiment of the present invention.

FIG. 7 is a sectional view of a communication module 200 according to a second preferred embodiment of the present invention.

FIG. 8 is a sectional view of a communication module 300 according to a third preferred embodiment of the present invention.

FIG. 9 shows a set of plan views illustrating upper principal surfaces of magnetic element layers 33x and 3c that define a multilayer substrate 1 of the communication module 300.

FIG. 10 is a sectional view of a communication module 1000 disclosed in Japanese Unexamined Patent Application Publication No. 2014-79014.

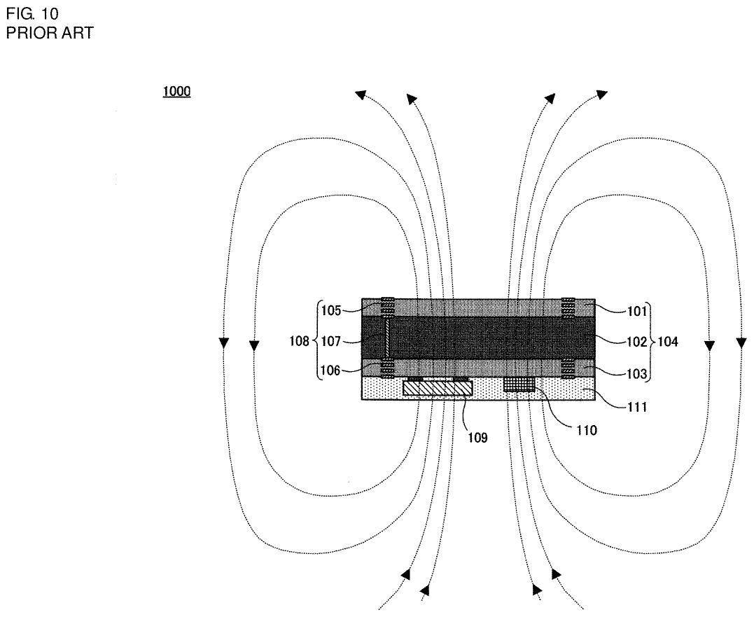

### DETAILED DESCRIPTION OF THE PREFERRED EMBODIMENTS

Preferred embodiments of the present invention will be described below with reference to the drawings.

A communication module according to a preferred embodiment of the present invention is defined as described above. In the above-described communication module, the communication circuit unit may include an IC. In this case, the communication circuit unit can easily be defined using the IC. The communication circuit unit is not always defined only by the IC, and it may be defined by the IC, one or more passive components, or the like, for example.

In the above-described communication module, the wiring provided in the resin layer may be a metal pole. In this case, the wiring can easily be provided using the metal pole. In this connection, the outer electrode may be an end surface of the metal pole, the end surface being exposed at the outer surface of the resin layer. In such a case, the outer electrode can easily be provided using the end surface of the metal pole.

When seeing through the communication module in a direction perpendicular or substantially perpendicular to the first principal surface and the second principal surface of the multilayer substrate, the ground electrode and the IC may at least partly overlap with each other. In this case, the IC can be satisfactorily shielded by the ground electrode. An outer edge of the IC may be positioned inside an outer edge of the ground electrode. In such a case, the IC can be more satisfactorily shielded by the ground electrode.

When seeing through the communication module in the direction perpendicular or substantially perpendicular to the first principal surface and the second principal surface of the multilayer substrate, the ground electrode and the coil antenna may at least partly overlap with each other. In this case, a magnetic field generated by the coil antenna can be successfully reduced or prevented from affecting the communication circuit unit. An outer edge of the coil antenna may be positioned inside the outer edge of the ground electrode. In such a case, the magnetic field generated by the coil antenna can be more successfully reduced or prevented from affecting the communication circuit unit.

When seeing through the communication module in a spread direction of the first principal surface and the second principal surface of the multilayer substrate, the ground electrode may be located inside the magnetic layer at a position closer to the first principal surface than to the non-magnetic layer. In this case, the communication module can secure, in the magnetic layer, a partial magnetic layer with a sufficient thickness enabling the magnetic field (magnetic flux) generated by the coil antenna to pass therethrough.

A shield conductor may be provided on or in a side surface of the resin layer. In this case, the shield conductor can reduce or prevent not only noise from entering the communication circuit unit from the outside, but also noise from being radiated to the outside from the communication circuit unit via the side surface of the resin layer. The shield conductor and the ground electrode may be electrically connected to each other. In such a case, a shield effect of the shield conductor is improved.

A capacitor electrode may be provided inside the magnetic layer at a position closer to the first principal surface than the ground electrode, and a capacitor may be defined by an electrostatic capacity generated between the capacitor electrode and the ground electrode. In this case, the capacitor can be utilized to define, for example, a matching circuit between the communication circuit unit and the coil antenna.

A passive component defining a portion of the communication circuit unit and/or a passive component not defining a portion of the communication circuit unit may be mounted to the first principal surface of the multilayer substrate. In this case, the mounted passive component can be used as a portion of the communication circuit unit. Alternatively, the mounted passive component can be utilized to define, for example, the matching circuit between the communication circuit unit and the coil antenna.

Several preferred embodiments of the present invention will be described below. However, the preferred embodiments represent specific examples of the present invention as illustrative only, and the present invention is not limited to the elements and features disclosed in the preferred embodiments. The element and features disclosed in the different preferred embodiments may be combined with each other to implement the present invention, and modifications obtained in those cases also fall within the scope of the present invention. The drawings merely aid understanding of the present invention. In some cases, the drawings are illustrated in simplified configurations and, in some other cases, size ratios in individual ones of illustrated elements or between the illustrated different elements are not matched with those explained in the description. Moreover, elements explained in the Description are omitted from the drawings or illustrated in reduced number depending on the case.

### First Preferred Embodiment

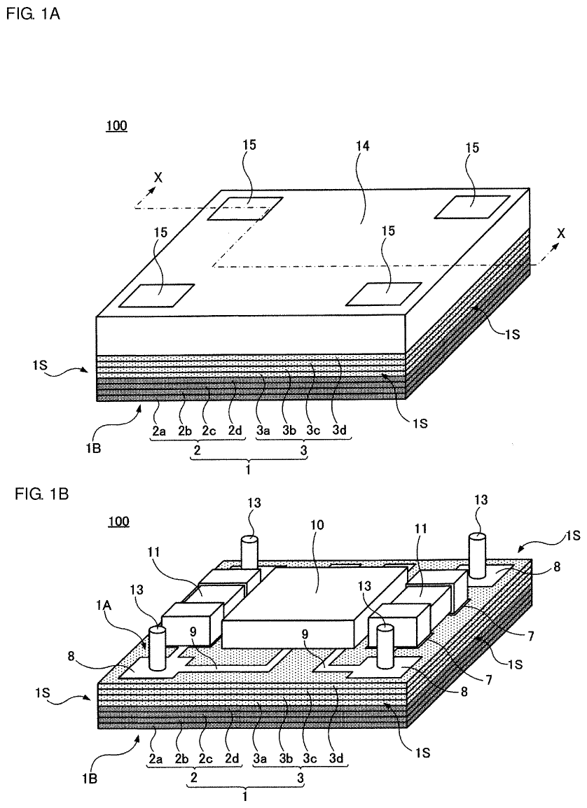

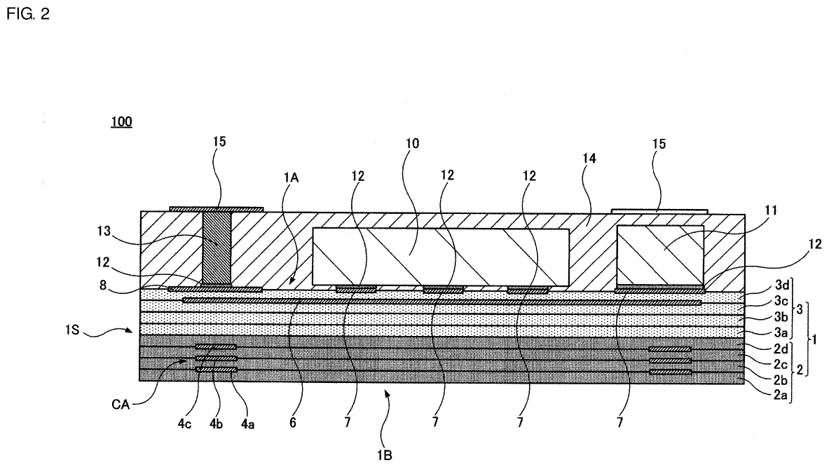

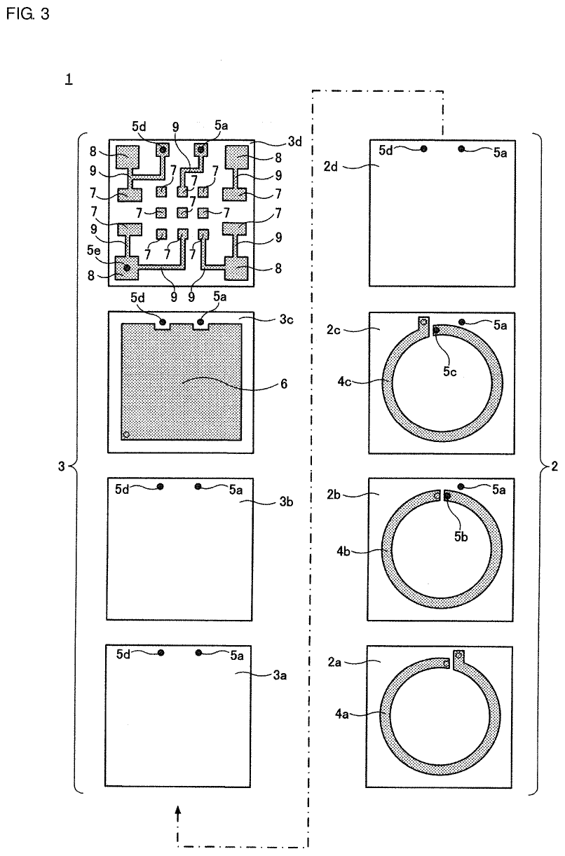

FIGS. 1A, 1B, 2, and 3 illustrate a communication module 100 according to a first preferred embodiment of the present invention. FIG. 1A is a perspective view of the communication module 100, and FIG. 1B is an exploded perspective view of the communication module 100 with omission of a resin layer 14 and an outer electrode 15. FIG. 2 is a sectional view of the communication module 100, the view illustrating an X-X section denoted by a one-dot-chain line in FIG. 1A. FIG. 3 represents a set of plan views of non-magnetic element layers 2a to 2d and magnetic element layers 3a to 3d that are laminated to define a multilayer substrate 1 of the communication module 100.

The communication module 100 is a communication module for a radio communication device utilizing NFMI (Near Field Magnetic Induction). However, the radio communication mode is optionally selected and it is not limited to NFMI. The communication module may operate in accordance with NFC (Near Field Communication) or any other suitable radio communication mode. Moreover, the communication module 100 may be used in medium-field or far-field communication without being limited to the near field communication.

The communication module 100 includes the multilayer substrate 1. The multilayer substrate 1 includes a non-magnetic layer 2 and a magnetic layer 3. The non-magnetic layer 2 is defined by laminating four non-magnetic element layers 2a, 2b, 2c and 2d. The magnetic layer 3 is defined by laminating four magnetic element layers 3a, 3b, 3c and 3d. The number of layers defining the non-magnetic layer 2 and the number of layers defining the magnetic layer 3 are each optionally selected and can be increased or decreased from the above-described values.

A material of the non-magnetic layer 2 (non-magnetic element layers 2a to 2d) is optionally selected and, for example, a non-magnetic ferrite ceramic material may preferably be used. A material of the magnetic layer 3 (magnetic element layers 3a to 3d) is also optionally selected and, for example, a magnetic ferrite ceramic material may preferably be used. In the description, the word “non-magnetic” is used in the expression “non-magnetic layer 2” for the sake of convenience, but the non-magnetic layer may be a layer with a certain level of magnetic permeability. Even when the non-magnetic layer 2 has a certain level of magnetic permeability, the magnetic permeability of the non-magnetic layer 2 is lower than that of the magnetic layer 3 in the frequency band in which the communication module is used (for example, the frequency band used in NFMI in this preferred embodiment).

The communication module 100 includes a first principal surface 1A on the upper side in FIGS. 1A, 1B, and 2 and a second principal surface 1B on the lower side. The first principal surface 1A and the second principal surface 1B are connected to each other by four side surfaces 1S.

Details of the non-magnetic element layers 2a to 2d and the magnetic element layers 3a to 3d will be described below with reference to FIG. 3.

A C-shaped coil pattern 4a is provided on or in an upper principal surface of the non-magnetic element layer 2a.

A C-shaped coil pattern 4b is provided on or in an upper principal surface of the non-magnetic element layer 2b. Via conductors 5a and 5b penetrate between both principal surfaces of the non-magnetic element layer 2b. The via conductor 5a is provided outside the coil pattern 4b and is connected to one end of the coil pattern 4a. The via conductor 5b is provided at one end of the coil pattern 4b and is connected to the other end of the coil pattern 4a.

A C-shaped coil pattern 4c is provided on or in an upper principal surface of the non-magnetic element layer 2c. Via conductors 5a and 5c penetrate between both principal surfaces of the non-magnetic element layer 2c. The via conductor 5a is provided outside the coil pattern 4c. The via conductor 5c is provided at one end of the coil pattern 4c and is connected to the other end of the coil pattern 4b.

Via conductors 5a and 5d penetrate between both principal surfaces of the non-magnetic element layer 2d. The via conductor 5d is connected to the other end of the coil pattern 4c.

Via conductors 5a and 5d penetrate between both principal surfaces of the magnetic element layer 3a.

Via conductors 5a and 5d penetrate between both principal surfaces of the magnetic element layer 3b.

A ground electrode 6 is provided on or in an upper principal surface of the magnetic element layer 3c. Via conductors 5a and 5d penetrate between both principal surfaces of the magnetic element layer 3c. The via conductors 5a and 5d are each provided at a position spaced away from the ground electrode 6.

Component mounting electrodes 7, relay electrodes 8, and wirings 9 are provided on or in an upper principal surface of the magnetic element layer 3d. The component mounting electrodes 7 and the relay electrodes 8 are connected in a predetermined layout by the wirings 9. Via conductors 5a, 5d and 5e penetrate between both the principal surfaces of the magnetic element layer 3d. The via conductors 5a, 5d and 5e are each provided at a predetermined position in the wiring 9 or the relay electrode 8. The via conductor 5e is connected to the ground electrode 6.

Materials of the coil patterns 4a to 4c, the via conductors 5a to 5e, the ground electrode 6, the component mounting electrodes 7, the relay electrodes 8, and the wirings 9 are optionally selected and, for example, Ag may preferably be used. Surfaces of the component mounting electrodes 7, the relay electrodes 8, and the wirings 9 may be covered with plating layers as required.

Inside the non-magnetic layer 2, a coil antenna CA is defined by a conductive path interconnecting the coil pattern 4a, the via conductor 5b, the coil pattern 4b, the via conductor 5c, and the coil pattern 4c. One end and the other end of the coil antenna CA are connected by the via conductor 5a and the via conductor 5d, respectively, to predetermined positions in the wirings 9 that are provided on or in the upper principal surface of the magnetic element layer 3d.

As illustrated in FIGS. 1B and 2, an IC 10 and a passive component 11 are mounted to the first principal surface 1A of the multilayer substrate 1. More specifically, one IC 10 and two passive components 11 are bonded using solders 12 to the component mounting electrodes 7 that are provided on or in the first principal surface 1A of the multilayer substrate 1. Note that outer electrodes disposed on the IC 10 and the two passive components 11 and bonded to the multilayer substrate 1 using the solders 12 are omitted in FIG. 2 and so on.

The IC 10 defines a communication circuit unit of the communication module 100. In the present preferred embodiment, the communication circuit unit of the communication module 100 is defined by only one IC 10. However, the communication circuit unit may be defined by the IC 10 and one or more passive components instead of the IC 10 alone.

The passive component 11 is preferably, for example, a coil or a capacitor. The number of the passive components 11 is optionally selected. Thus, only one passive component 11 may be mounted, or three or more passive components 11 may be mounted. The passive component 11 is not a necessary component and it may be omitted. In the present preferred embodiment, the passive component 11 defines a matching circuit to provide matching between the communication circuit unit (IC 10) and the coil antenna CA. However, the passive component 11 may be used as an electronic component defining the communication circuit unit, instead of or in addition to constituting the matching circuit. Alternatively, the passive component 11 may be used to define a circuit other than the matching circuit.

A metal pole (wiring) 13 is mounted to the first principal surface 1A of the multilayer substrate 1. More specifically, the metal pole 13 preferably having a cylindrical shape and made of Cu, for example is bonded, using a solder 12, to each of four relay electrodes 8 that are provided on the first principal surface 1A of the multilayer substrate 1. The metal pole 13 is defined by, for example, a metal pin obtained by carving out a metal block. The number, material, shape and so on of the metal pole 13 are optionally selected. For example, the metal pole 13 may have a prismatic shape, instead of the cylindrical shape.

As illustrated in FIGS. 1A and 2, the resin layer 14 is provided on the first principal surface 1A of the multilayer substrate 1 to cover the IC 10, the passive components 11, and the metal poles 13. A material of the resin layer 14 is optionally selected and, for example, epoxy resin may preferably be used. In addition, inorganic filler may be mixed into the resin layer 14.

Four outer electrodes 15 are provided on or in an outer surface of the resin layer 14. The outer electrodes 15 are connected to the metal poles 13 in a one-to-one relationship. A structure, a material, and so on of each outer electrode 15 are optionally selected. In the present preferred embodiment, the outer electrode 15 preferably has a three-layer structure including, for example, a close contact layer made of SUS, a conductive layer made of Cu, and a protective layer made of SUS with a thin film technique such as sputtering, for example. The number of layers of the outer electrodes 15 is optionally selected, and the outer electrode 15 is not limited to the three-layer structure. For example, the outer electrode 15 may have a one-layer or two-layer structure.

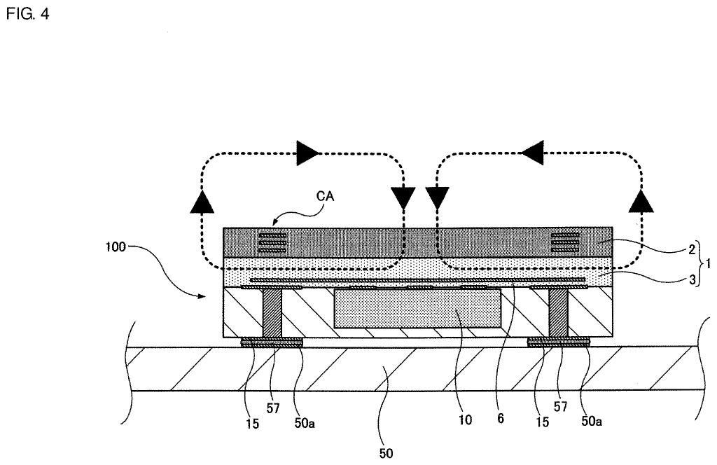

FIG. 4 illustrates an example of usage of the communication module 100. The communication module 100 is reversed in posture from the example in the above-described description and is used in a state in which the outer electrodes 15 are bonded, using a solder 57, to electrodes 50a provided on or in a circuit board 50. The circuit board 50 to which the communication module 100 is mounted as described above is disposed inside a housing (not illustrated) and is used as an electronic device. Examples of the electronic device include a telephone such as a smartphone, a tablet PC, a game machine, a headphone, and a notebook personal computer.

In FIG. 4, a magnetic field (magnetic flux) generated by the coil antenna CA of the communication module 100 is denoted by dotted lines with arrows. The communication module 100 is designed such that the magnetic field generated by the coil antenna CA is bent inside the magnetic layer 3 of the multilayer substrate 1 to extend in a spread direction of the magnetic layer 3 and hardly reaches the communication circuit unit (IC 10) mounted to the multilayer substrate 1. According to the communication module 100, since formation of the magnetic field by the coil antenna CA is not impeded by the communication circuit unit, a sufficiently long communication distance can be obtained.

When seeing through the communication module 100 in a direction perpendicular or substantially perpendicular to the first principal surface 1A and the second principal surface of the multilayer substrate 1, the ground electrode 6 and the IC 10 overlap with each other. In more detail, an outer edge of the IC 10 is positioned inside an outer edge of the ground electrode 6. Thus, according to the communication module 100, since the communication circuit unit (IC 10) is shielded by the ground electrode 6, noise is less likely to enter the communication circuit unit from the outside and noise is less likely to be radiated to the side including the coil antenna CA and to the outside from the communication circuit unit.

Furthermore, when seeing through the communication module 100 in the direction perpendicular or substantially perpendicular to the first principal surface 1A and the second principal surface of the multilayer substrate 1, the ground electrode 6 and the coil antenna CA overlap with each other. In more detail, an outer edge of the coil antenna CA is positioned inside the outer edge of the ground electrode 6. Accordingly, in the communication module 100, the magnetic field generated by the coil antenna CA is reduced or prevented from affecting the communication circuit unit (IC 10).

Moreover, when seeing through the communication module 100 in a spread direction of the first principal surface 1A and the second principal surface 1B of the multilayer substrate 1, the ground electrode 6 is located inside the magnetic layer 3 at a position closer to the first principal surface 1A than to the non-magnetic layer 2. Accordingly, the communication module 100 can secure, in the magnetic layer 3, a partial magnetic layer (corresponding to the magnetic element layers 3a to 3c) with a sufficient thickness enabling the magnetic field generated by the coil antenna CA to pass therethrough.

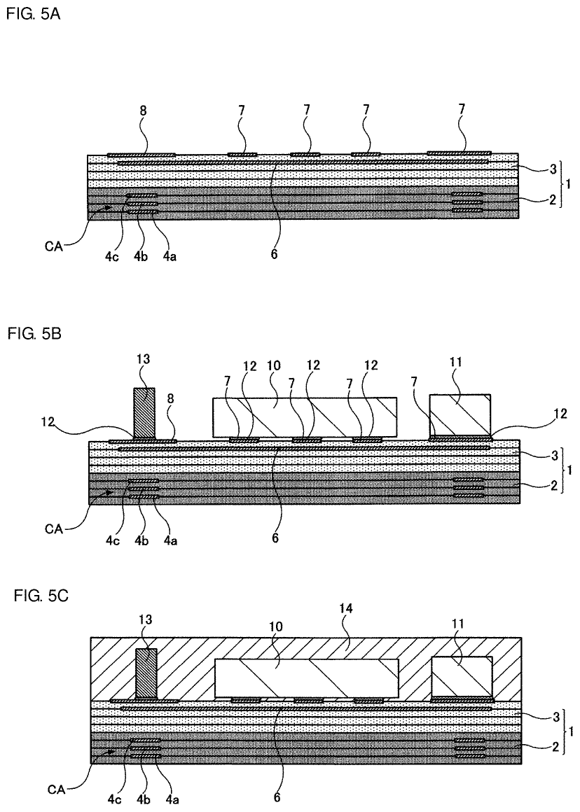

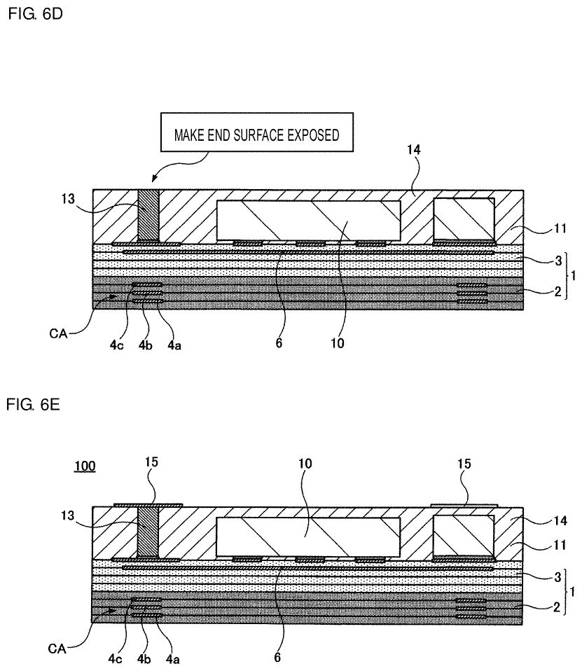

The communication module 100 can be manufactured by a method illustrated in FIGS. 5A to 6E, for example. According to a method used in an actual manufacturing process, it is typical to use mother green sheets in each of which many green sheets are arrayed in a matrix pattern, to manufacture many communication modules 100 together, and to divide them into the individual communication modules 100 during the manufacturing process. For convenience of explanation, however, the following description is made in connection with the case of manufacturing one communication module 100.

First, the multilayer substrate 1 illustrated in FIG. 5A is fabricated. More specifically, ceramic green sheets made of a non-magnetic substance and used to form the non-magnetic element layers 2a to 2d and ceramic green sheets made of a magnetic substance and used to form the magnetic element layers 3a to 3d are prepared. Then, in order to form the via conductors 5a to 5e, through-holes are formed in predetermined ones of the green sheets at predetermined positions, and a conductive paste is filled into the through-holes. Then, in order to form the coil patterns 4a to 4c, the ground electrode 6, the component mounting electrodes 7, the relay electrodes 8, and the wirings 9, a conductive paste is coated in predetermined pattern shapes over principal surfaces of predetermined ones of the green sheets. Then, the green sheets are laminated and integrated into a one-piece structure, thus fabricating a multilayer substrate not yet fired. Then, the not-yet-fired multilayer substrate is fired in accordance with a predetermined profile, such that the multilayer substrate 1 illustrated in FIG. 5A is obtained.

Then, plating layers are formed on surfaces of the component mounting electrodes 7, the relay electrodes 8, and the wirings 9 as required.

Then, as illustrated in FIG. 5B, the IC 10 and the passive components 11 are mounted to the component mounting electrodes 7 and the metal poles 13 are mounted to the relay electrodes 8, respectively, using the solders 12. More specifically, after coating a solder paste over the surfaces of the component mounting electrodes 7 and the relay electrodes 8 in advance, the IC 10, the passive components 11, and the metal pole 13 are placed on the coated solder paste. Then, the solder paste is heated to be molten. Then, the molten solder is naturally cooled to be solidified again, such that the IC 10 and the passive components 11 are bonded to the component mounting electrodes 7 and the metal poles 13 are bonded to the relay electrodes 8, respectively, using the solders 12.

Then, as illustrated in FIG. 5C, the resin layer 14 is formed on the first principal surface 1A of the multilayer substrate 1 to cover the IC 10, the passive components 11, and the metal poles 13. More specifically, after supplying a semi-molten resin material onto the first principal surface 1A of the multilayer substrate 1 to cover the IC 10, the passive components 11, and the metal poles 13, the resin material is heated to be cured, such that the resin layer 14 is formed on the first principal surface 1A of the multilayer substrate 1.

Then, as illustrated in FIG. 6D, an outer surface of the resin layer 14 is scraped to expose end surfaces of the metal poles 13 at the outer surface of the resin layer 14.

Then, as illustrated in FIG. 6E, the outer electrodes 15 each having a predetermined shape are formed on or in the outer surface of the resin layer 14 at predetermined positions with, for example, a thin film technique, such as sputtering.

Through the above-described steps, the communication module 100 is completed.

### Second Preferred Embodiment

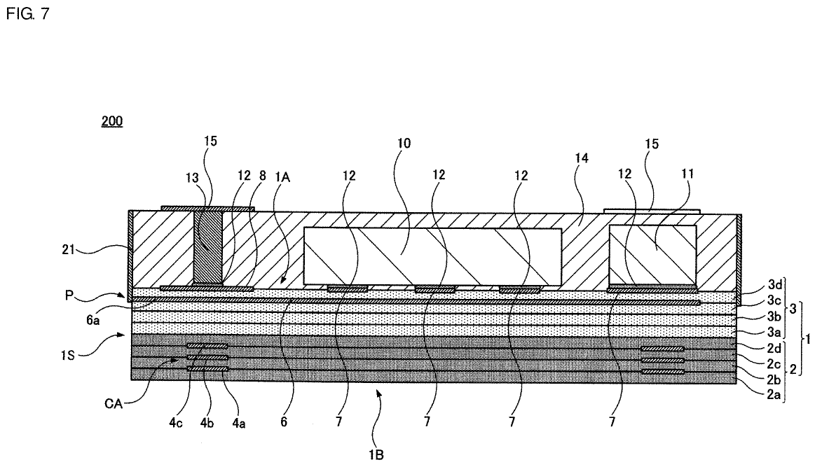

FIG. 7 illustrates a communication module 200 according to a second preferred embodiment of the present invention. FIG. 7 is a sectional view of the communication module 200.

The communication module 200 according to the second preferred embodiment is provided by adding a component to the communication module 100 according to the first preferred embodiment. More specifically, in the communication module 200, a shield conductor 21 is provided on the four side surfaces of the resin layer 14 in the communication module 100. The shield conductor 21 has a ring shape and surrounds the four side surfaces of the resin layer 14.

Furthermore, in the communication module 200, the shield conductor 21 extends to a position covering a side surface of the magnetic element layer 3d in the magnetic layer 3 of the multilayer substrate 1, and one or more conductive paths 6a extending from the ground electrode 6 to the side surface 1S of the multilayer substrate 1 are provided. The shield conductor 21 and the conductive path 6a are electrically connected to each other at a point P. Therefore, the shield conductor 21 has a ground potential, and a shield effect is improved.

Alternatively, the shield conductor 21 may be provided with the ground potential by connecting the shield conductor 21 to the wiring 9 that is provided on the first principal surface of the multilayer substrate 1 and that has the ground potential, instead of connecting the shield conductor 21 to the ground electrode 6.

The shield conductor 21 can be formed by sputtering, for example. A structure, a material, a thickness, and so on of the shield conductor 21 are optionally selected. In the present preferred embodiment, the shield conductor 21 preferably has a three-layer structure including, for example, a close contact layer made of SUS, a conductive layer made of Cu, and a protective layer made of SUS. The close contact layer and the protective layer may be made of Cr, Ni or Ti, for example, instead of SUS. The conductive layer may be made of Ag or Al, for example, instead of Cu. The number of layers of the shield conductor 21 is optionally selected, and the shield conductor 21 is not limited to the three-layer structure. For example, the shield conductor 21 may have a one-layer or two-layer structure.

In the communication module 200, the communication circuit unit (IC 10) is shielded from the outside by not the ground electrode 6 alone, but by both the ground electrode 6 and the shield conductor 21. According to the communication module 200, therefore, noise is less likely to enter the communication circuit unit from the outside and noise is less likely to be radiated to the outside from the communication circuit unit than in the communication module 100.

### Third Preferred Embodiment

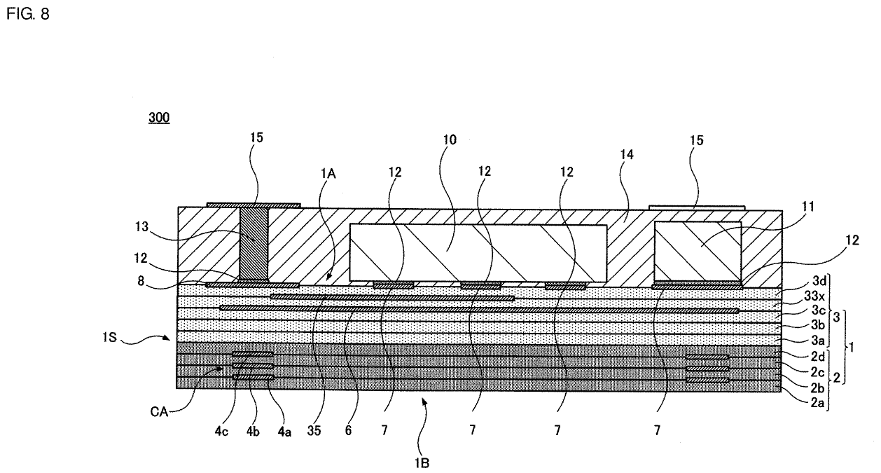

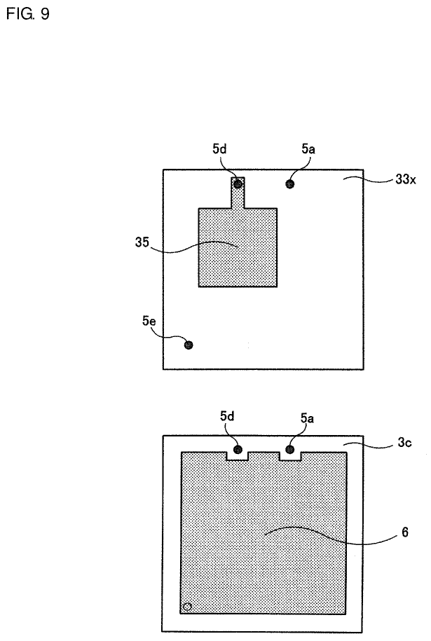

FIGS. 8 and 9 illustrate a communication module 300 according to a third preferred embodiment of the present invention. FIG. 8 is a sectional view of the communication module 300. FIG. 9 represents a set of plan views illustrating upper principal surfaces of magnetic element layers 33x and 3c that define a multilayer substrate 1 of the communication module 300.

The communication module 300 according to the third preferred embodiment is also provided by adding a component to the communication module 100 according to the first preferred embodiment. More specifically, in the communication module 300, an additional magnetic element layer 33x is added between the magnetic element layer 3c and the magnetic element layer 3d that constitute the magnetic layer 3 of the multilayer substrate 1 in the communication module 100.

As illustrated in FIG. 9, a capacitor electrode 35 is provided on or in the upper principal surface of the magnetic element layer 33x. The capacitor electrode 35 is electrically connected to the via conductor 5d.

As illustrated in FIG. 8, the capacitor electrode 35 is positioned opposite to the ground electrode 6 with the magnetic element layers 33x interposed therebetween. A capacitor is defined by an electrostatic capacity generated between the capacitor electrode 35 and the ground electrode 6. The capacitor can be utilized, for example, as an electronic element that defines the matching circuit to provide matching between the communication circuit unit (IC 10) and the coil antenna CA. However, the application of the capacitor is not limited to the matching circuit, and the capacitor may be used as an electronic element defining any other suitable circuit.

The communication modules 100, 200 and 300 according to the first, second and third preferred embodiments have been described above. However, the present invention is not limited to the above-described preferred embodiments, and the present invention can be variously modified without departing from the gist of the invention.

For example, in the communication modules 100, 200 and 300, the coil antenna CA is defined by the coil patterns 4a, 4b and 4c that are provided between adjacent pairs of the non-magnetic element layers 2a to 2d, and the coil antenna CA is provided inside the non-magnetic layer 2. However, a position where the coil antenna CA is to be provided is not limited to the inside of the non-magnetic layer 2, and the coil antenna CA may be provided at positions inside the non-magnetic layer 2 and on an outer surface thereof by providing a coil pattern on a lower principal surface of the non-magnetic layer 2a as well. In another example, the coil antenna CA may be provided at a position on the outer surface of the non-magnetic layer 2 by providing a coil pattern only on the lower principal surface of the non-magnetic layer 2a without providing any coil patterns between adjacent pairs of the non-magnetic element layers 2a to 2d. In another example, a coil pattern may be additionally provided between the non-magnetic element layer 2d and the magnetic element layer 3a, or a coil pattern may be provided only between the non-magnetic layer 2d and the magnetic element layer 3a.

While, in the communication modules 100, 200 and 300, the outer electrode 15 is provided on the outer surface of the resin layer 14, the end surface of the metal pole 13 may be exposed at the outer surface of the resin layer 14, and the end surface of the metal pole 13 exposed at the outer surface of the resin layer 14 may be used as the outer electrode instead of separately providing the outer electrode. In such a case, a plating layer may be provided on the end surface of the metal pole 13.

Moreover, in the communication modules 100, 200 and 300, the metal pole 13 is used as the wiring electrically connecting the relay electrode 8 provided in the resin layer 14 and the outer electrode 15. However, the wiring electrically connecting the relay electrode 8 and the outer electrode 15 is not limited to the metal pole 13, and it may be a via conductor obtained by providing a through-hole in the resin layer 14 and filling a conductive material into the through-hole, or a via conductor obtained by coating a conductive material on an inner wall of the above-mentioned through-hole.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A communication module comprising:
a multilayer substrate including a first principal surface, a second principal surface, and at least one side surface that connects the first principal surface and the second principal surface;
a coil antenna;
a component mounting electrode provided on or in the first principal surface of the multilayer substrate;
a communication circuit unit mounted to the first principal surface of the multilayer substrate with the component mounting electrode interposed therebetween; and
a resin layer covering the communication circuit unit on a first principal surface side of the multilayer substrate;
wherein
the multilayer substrate includes a magnetic layer and a non-magnetic layer;
the magnetic layer is positioned on a side closer to the first principal surface of the multilayer substrate;
the non-magnetic layer is positioned on a side closer to the second principal surface of the multilayer substrate;
the coil antenna is located at a position in contact with the non-magnetic layer;
a ground electrode is provided inside the magnetic layer;
a relay electrode is provided on or in the first principal surface of the multilayer substrate;
an outer electrode is provided on or in an outer surface of the resin layer; and
a wiring electrically connecting the relay electrode and the outer electrode is provided in the resin layer.

2. The communication module according to claim 1, wherein the communication circuit unit includes an IC.

3. The communication module according to claim 1, wherein the wiring is a metal pole.

4. The communication module according to claim 3, wherein the outer electrode is an end surface of the metal pole, and the end surface is exposed at the outer surface of the resin layer.

5. The communication module according to claim 2, wherein, when seeing through the communication module in a direction perpendicular or substantially perpendicular to the first principal surface and the second principal surface of the multilayer substrate, the ground electrode and the IC at least partly overlap with each other.

6. The communication module according to claim 5, wherein an outer edge of the IC is inside an outer edge of the ground electrode.

7. The communication module according to claim 1, wherein, when seeing through the communication module in a direction perpendicular or substantially perpendicular to the first principal surface and the second principal surface of the multilayer substrate, the ground electrode and the coil antenna at least partly overlap with each other.

8. The communication module according to claim 7, wherein an outer edge of the coil antenna is inside an outer edge of the ground electrode.

9. The communication module according to claim 1, wherein, when seeing through the communication module in a spread direction of the first principal surface and the second principal surface of the multilayer substrate, the ground electrode is located inside the magnetic layer at a position closer to the first principal surface than to the non-magnetic layer.

10. The communication module according to claim 1, wherein a shield conductor is provided on or in a side surface of the resin layer.

11. The communication module according to claim 10, wherein the shield conductor and the ground electrode are electrically connected to each other.

12. The communication module according to claim 1, wherein
a capacitor electrode is provided inside the magnetic layer at a position closer to the first principal surface than the ground electrode; and
a capacitor is defined by an electrostatic capacity generated between the capacitor electrode and the ground electrode.

13. The communication module according to claim 1, wherein a passive component defining a portion of the communication circuit unit and/or a passive component not defining a portion of the communication circuit unit is mounted to the first principal surface of the multilayer substrate.

14. An electronic device comprising:
a communication module; and
a circuit board to which the communication module is mounted; wherein
the communication module includes:
a multilayer substrate including a first principal surface, a second principal surface, and at least one side surface that connects the first principal surface and the second principal surface;
a coil antenna;
a component mounting electrode provided on or in the first principal surface of the multilayer substrate;
a communication circuit unit mounted to the first principal surface of the multilayer substrate with the component mounting electrode interposed therebetween; and
a resin layer covering the communication circuit unit on a first principal surface side of the multilayer substrate;
the multilayer substrate includes a magnetic layer and a non-magnetic layer;
the magnetic layer is positioned on a side closer to the first principal surface of the multilayer substrate;
the non-magnetic layer is positioned on a side closer to the second principal surface of the multilayer substrate;
the coil antenna is located at a position in contact with the non-magnetic layer;
a ground electrode is provided inside the magnetic layer,
a relay electrode is provided on or in the first principal surface of the multilayer substrate;
an outer electrode is provided on or in an outer surface of the resin layer;
a wiring electrically connecting the relay electrode and the outer electrode is provided in the resin layer; and
the communication module is mounted to the circuit board with the outer electrode interposed therebetween.

15. A communication module manufacturing method comprising:
a step of preparing a plurality of green sheets made of a magnetic substance and a plurality of green sheets made of a non-magnetic substance;
a step of, to form via conductors, forming through-holes at positions in one or more among the plurality of green sheets made of the magnetic substance and one or more among the plurality of green sheets made of the non-magnetic substance, and filling a conductive paste into the through-holes;
a step of coating a conductive paste in a pattern shape over a principal surface of each of one or more of the plurality of green sheets made of the magnetic substance and one or more of the plurality of green sheets made of the non-magnetic substance to form at least one selected from a coil pattern, a ground electrode, a component mounting electrode, a relay electrode, and a wiring;
a step of laminating the plurality of green sheets made of the magnetic substance and the plurality of green sheets made of the non-magnetic substance, integrating the laminated green sheets into a one-piece structure, and firing the green sheets to fabricate a multilayer substrate that has a first principal surface, a second principal surface, and at least one side surface connecting the first principal surface and the second principal surface, and that includes a magnetic layer formed on a side closer to the first principal surface, a non-magnetic layer formed on a side closer to the second principal surface, and a coil antenna formed by the coil pattern at a position in contact with the non-magnetic layer;
a step of bonding an electronic component to the component mounting electrode formed on or in the first principal surface of the multilayer substrate, and bonding a metal pole to the relay electrode formed on or in the first principal surface of the multilayer substrate;
a step of forming a resin layer on a first principal surface side of the multilayer substrate to cover the electronic component and the metal pole; and
a step of scraping an outer surface of the resin layer to make an end surface of the metal pole exposed at the outer surface of the resin layer.

16. The electronic device according to claim 14, wherein the communication circuit unit includes an IC.

17. The electronic device according to claim 14, wherein the wiring is a metal pole.

18. The electronic device according to claim 17, wherein the outer electrode is an end surface of the metal pole, and the end surface is exposed at the outer surface of the resin layer.

19. The electronic device according to claim 16, wherein, when seeing through the communication module in a direction perpendicular or substantially perpendicular to the first principal surface and the second principal surface of the multilayer substrate, the ground electrode and the IC at least partly overlap with each other.

20. The electronic device according to claim 19, wherein an outer edge of the IC is inside an outer edge of the ground electrode.
